(19) United States
(12) Patent Application Publication
(10) Pub. No.: US 2001/0053559 A1
(43) Pub. Date: Dec. 20, 2001

(54) Method of fabricating display device

(75) Inventors: Ritsuko Nagao, Kanagawa (JP); Satoshi Murakami, Kanagawa (JP); Misako Nakazawa, Kanagawa (JP)

Correspondence Address: COOK, ALEX, MCFARRON, MANZO,, CUMMINGS & MEHLER, LTD., Suite 2850, 200 West Adams St., Chicago, IL, 60606, US

(73) Assignee: Semiconductor Energy Laboratory Co., Ltd.

(21) Appl. No.: 09/768,133

(22) Filed: Jan. 23, 2001

(30) Foreign Application Priority Data
Jan. 25, 2000 (JP) 2000-016309

(51) Int. Cl. H01L 21/00

(52) U.S. Cl. 438/30; 438/29; 438/27

(57) ABSTRACT

The present invention improves the reliability of wirings, facilitates the orientation control of liquid crystal, or improves a reflectance of a reflective liquid crystal display device. In the case where a plurality of levelling films are laminated, a first levelling film is formed to have a thickness smaller than that of a second levelling film, thereby realizing a higher levelling rate. Therefore, unevenness of the surface due to level differences is reduced and it becomes possible to attain the above objects.

### BACKGROUND OF THE INVENTION

1. Field of the Invention

The present invention relates to a method of fabricating a display device in which thin film transistors (hereinafter abbreviated as TFTs) are used as switching elements.

2. Description of the Related Art

An active matrix liquid crystal display device is widely used for OA equipment, television sets and the like because a clear image can be obtained by controlling the application of a voltage to liquid crystal for each pixel with TFTs formed on a transparent substrate such as a glass substrate. In order to realize clearer display of characters or geometric patterns, it is required to enhance definition by reducing the size of each pixel.

With such recent trend toward finer display, an interlayer insulating film serving as an insulating layer between wirings is required to be made of a material having a high insulating property as well as high productivity with little occurrence of level differences or breaking of wire when a wiring is to be formed in a fabrication process.

Although a film-formation method requiring a vacuum system such as CVD or vapor deposition and a spin coating method are both considered as fabrication methods for such an interlayer insulating film material, a spin-coating method is advantageous in terms of productivity and ability of covering a level difference (flatness). According to the spin-coating method, a varnish in which each insulating material or a precursor of the insulating material is dissolved in a solvent is discharged over a substrate. Then, the substrate is spun so that the varnish is uniformly applied thereto. The substrate on which the varnish is applied is baked in an oven or on a hot plate to obtain an insulating film.

The thickness of the insulating film is controlled by the number of spinnings, the period of spinning time, the concentration and the viscosity of the varnish. A material used for spin-coating can be selected from a polyimide resin, an acrylic resin, a resin containing a siloxane structure, an inorganic SOG (Spin on Glass) material and the like, in consideration of physical properties such as a transparence, a heat resistance, a chemical resistance, and a thermal expansion coefficient. In the case where a low dielectric property is considered as an important factor, an organic material is often used.

In the case where high flatness is desired to be realized, CMP (Chemical Mechanical Polishing) may be performed for the formed insulating film to form a completely flat surface. In practice, however, TFTs on the glass surface have many problems such as high equipment cost, uniformity and selectivity.

FIG. 2 shows a cross section of a conventional active matrix substrate. On a glass substrate 100, level differences generated by an active layer (including a channel region 101, a source region 102, and a drain region 103), a gate wiring 105, a source wiring 107, a drain wiring 108 and the like are present. A levelling resin, representatively an acrylic resin, is used to as a first levelling film 109 so as to level these level differences. Finally, a pixel electrode 111 is formed on the first levelling film 109 to complete the active matrix substrate.

Next, as shown in FIG. 3, the active matrix substrate is bonded to a counter substrate 120 so as to interpose liquid crystal 123 therebetween to form a liquid crystal display device. According to this conventional method of forming a levelling film, however, it is apprehended that the pixel electrode 111 might be broken because of insufficient flatness of the levelling film. Moreover, since the unevenness due to the level differences remains on the surface of the pixel electrode 111, poor orientation of the liquid crystal 123 is caused on the uneven region of the surface.

With the increased number of layers of a wiring, it is presumed that the generation of a level difference or the breaking of a wiring occurs when the wiring is formed. A first purpose of the present invention is to prevent the breaking of a wiring due to the level difference in an active matrix display device.

In the conventional structure shown in FIG. 2, since the metal wirings 105 and 107 are integrally formed on the substrate 100, the levelling film 109 is not sufficiently flat. Therefore, the liquid crystal 123 is poorly oriented by an uneven surface of the pixel electrode 111 as shown in FIG. 3. As a result, a uniform image cannot be obtained. Furthermore, although the poor orientation of liquid crystal caused due to the uneven surface can be hidden by providing a light-shielding pattern thereon, the unevenness is covered by the light-shielding pattern at the sacrifice of an aperture ratio. A second purpose of the present invention is to facilitate the orientation control of liquid crystal without reducing the aperture ratio so as to obtain uniform image display in the active matrix display device.

Since a reflectance of the surface of the pixel electrode 111 greatly affects the utilization efficiency of incident light, particularly in a reflective liquid crystal display device among active matrix liquid crystal display devices, a higher reflectance allows the realization of image display with higher brightness. Specifically, in the case where unevenness of the surface is great as shown in FIGS. 2 and 3, the reflectance is lowered for scattered incident light. The third purpose of the present invention is to improve the reflectance in a reflective liquid crystal display device.

### SUMMARY OF THE INVENTION

An object of the present invention is to, by achieving all three purposes described above, fabricate a display device with a highly reliable wiring, a high aperture ratio and a uniform image. At the same time, the present invention has another object to improve the quality and reliability of electric appliances using the display devices fabricated in accordance with the present invention.

In order to achieve the above first purpose, it is necessary to use an insulating film with excellent flatness. Japanese Patent Application Laid-open Nos. Hei 5-78453 and Hei 5-222195 disclose a material with excellent flatness formed by spin coating. Certainly, the increasing concentration of a solution used for spin coating is effective for improving the flatness, but there is a limit in increasing the concentration because the material is required to have a high solubility to a solvent and a viscosity that allows easy and uniform application thereof.

It is apparent that high flatness can be realized by laminating two or more layers of the material having a high levelling effect (levelling rate). In short, a higher levelling rate can be realized by forming a levelling film thicker. However, since an etching process of a levelling film for forming a through hole therein should be easy for high productivity, there is a limit in increasing the thickness of the levelling film.

Then, the inventors of the present invention have investigated a method of laminating a plurality of levelling films with high flatness without increasing the thickness of the levelling films. As a result, effective findings for improving the flatness have been made. The experimental result on which the result of the study is grounded is shown in FIGS. 5 and 6.

First, as an experimental sample, a wiring 401 of a linear protruding pattern having a thickness (initial level difference Hₒ) in the range of 0.16 to 0.75 μm and a width (designated by L) in the range of 5 to 100 μm is formed at constant intervals (designated by P) in the range of 10 to 400 μm on a glass substrate 400 as shown in FIG. 4. For facility of estimation, a plurality of sets of linear protruding patterns with different values of P and L, each set including five linear protruding patterns, are placed in the same substrate.

Next, a first levelling film 402 is formed on the wiring 401 by spin coating. Subsequently, a second levelling film 403 is formed on the first levelling film 402 in a similar manner. As means for estimating the flatness, a levelling rate is used. The levelling rate is obtained by substituting a value of the initial level difference Hₒ before formation of the levelling films and a value of a level difference h after formation of the levelling films in the following Expression (1). A levelling rate closer to 1 indicates higher flatness.

1−(h/Hₒ) (1)

where Hₒ represents a value of the initial level difference, and h represents a value of the level difference after formation of the levelling films.

A probe-type surface shape inspection device DEKTAK³ST (produced by ULVAC) is used for measuring the level difference, and a scanning rate is set to 10 μm/sec. The levelling film used in this experiment is an acrylic resin (SS6699/0699 produced by JSR). It is assumed that a thickness of the levelling film is that of the levelling film formed on the substrate when the initial level difference Hₒ=0.

First, the relationship between the thickness T₁ and the levelling rate is shown in FIG. 5. With the increase in the thickness T₁ of the levelling film, the levelling rate also increases. The tendency of increasing the levelling rate with the increase in the thickness T₁ does not depend on the value of P or L (not shown). Herein, it is assumed that a levelling film having the thickness T₁ is deposited. Since a levelling rate (R) is constant independently of a value of the level difference, the following Expression (2) can be established for the levelling rate obtained after deposition of the levelling layer having the thickness T₁.

1−(1−R)ⁿ (2)

where R represents a levelling rate, and n represents the number of layer depositions.

For example, a levelling rate (L/P=25/45 μm) with T₁=0.5 μm is 0.5. Based on the Expression (2), it is assumed that a levelling rate with two layers is 0.75 and that a levelling rate with three layers is 0.875. However, levelling rates with T₁=1.0 μm and T₁=1.5 μm are respectively 0.67 and 0.76. Therefore, it is understood that a levelling rate is obviously higher with laminated layers than with a single layer in the case where the same total thickness is achieved. Specifically, a levelling rate is more improved by forming the levelling film in a plurality of steps than forming it in a single step.

Next, in consideration of improvement of the levelling rate and productivity, the case where two-step formation of the levelling film is conducted is examined. For two-step formation of the levelling film, the thickness of the first levelling film 402 and the thickness of the second levelling film 403 shown in FIG. 4 are respectively designated by T₁ and T₂. The relationship between T₂/T₁ and a levelling rate when T₁+T₂=1.5 μm is shown in FIG. 6. The result shows that the levelling rate tends to be improved with a larger value of T₂/T₁. Specifically, in the case where a value of T₁+T₂ is constant, a higher levelling rate can be realized by setting the thickness T₁ of the first levelling film 402 smaller than the thickness T₂ of the second levelling film 403.

A difference in the levelling rate is considered to be generated because the level difference becomes gentler owing to the first levelling film 402 within a certain range of T₁, so that a levelling rate of the second levelling film 403 is improved as compared with a normal case where the level difference is rectangular.

As can be understood from the fact that a levelling rate is low with a single layer, it is assumed that the levelling rate begins to drop again when T₁ is reduced and T₂ is increased infinitely, that is, a value of T₂/T₁ is infinitely increased.

However, it is not easy to infinitely reduce or increase the thickness of the layer. Taking into consideration that the levelling film should have a thickness with good uniformity without unevenness in application, the thickness of the layer obtained by spinning application has the lower limit, that is, about 0.1 μm. Furthermore, the upper limit of the thickness of the layer which allows a through hole to be formed by wet etching or dry etching without any difficulty after the formation of the layer is about 3.0 μm.

The above-described tendency in FIG. 6 is established as long as T₁ is a thickness with good uniformity without unevenness in application. Specifically, when a value of T₁+T₂ is constant, T₁+T₂ is from 0.2 μm to 3.0 μm inclusive, with T₁ being 0.1 μm or more and less than 1.5 μm and T₂ being 0.1 μm or more and 2.9 μm or less.

FIG. 1 shows a cross section of a levelled active matrix substrate taking advantage of the above tendency. First, a TFT is formed in a similar manner as in the prior art shown in FIG. 2. Next, the first levelling film 109 is formed to have a thickness of 0.5 μm. Then, a second levelling film 110 is formed on the first levelling film 109 to have a thickness of 1.0 μm.

As the first levelling film 109 or the second levelling film 110, a polyimide resin, an acrylic resin, a resin containing a siloxane structure, or an inorganic SOG material can be used. The inorganic SOG material herein is made of an inorganic material which can be spin-coated. Specifically, PSG (Phosphosilicate Glass), BSG (Borosilicate Glass), BPSG (Borophosphosilicate Glass) and the like can be given as examples thereof.

In this way, a higher levelling rate can be achieved by forming the first and second levelling films having a large value of T₂/T₁, for example, T₁ is 0.5 μm and T₂ is 1.0 μm in forming the levelling film that has a total thickness of 1.5 μm.

On the thus obtained flat surface, the breaking of wirings and the poor orientation of liquid crystal due to unevenness of the surface hardly occur. Moreover, the decrease in aperture ratio by providing a light-shielding pattern can be avoided. Furthermore, in a reflective liquid crystal display device, a reflectance is improved owing to reduced unevenness of the surface. The inventors of the present invention have found that a levelling rate is remarkably improved by using the present invention, satisfying all the above first to third requirements.

### BRIEF DESCRIPTION OF THE DRAWINGS

In the accompanying drawings:

FIG. 1 is a cross-sectional view of a TFT with a levelling structure according to the present invention;

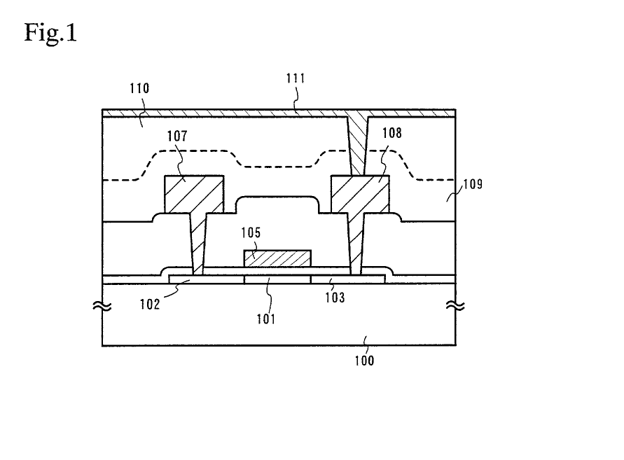

FIG. 2 is a cross-sectional view of a TFT with a conventional levelling structure;

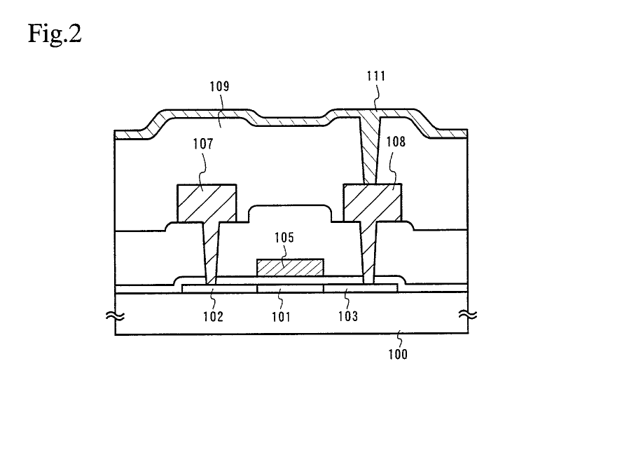

FIG. 3 is a cross-sectional view showing a liquid crystal display device using a conventional levelling structure;

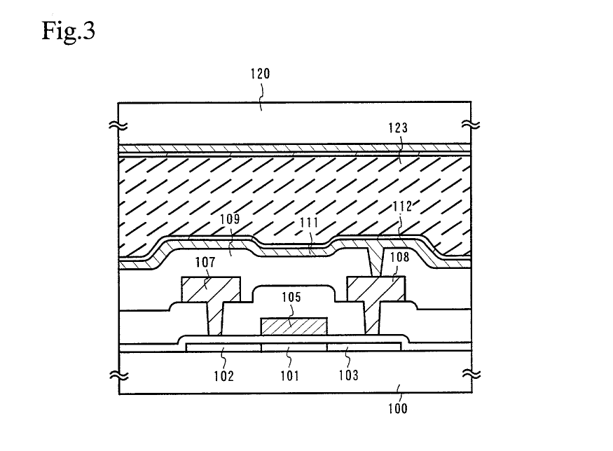

FIG. 4 is a diagram showing a cross-sectional structure of an experimental sample;

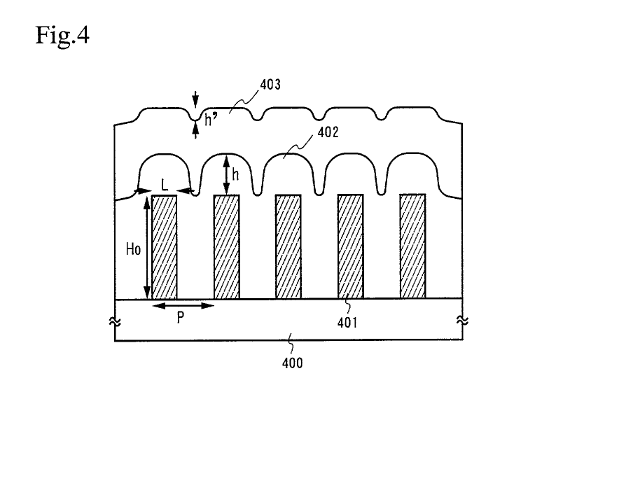

FIG. 5 is a graph showing the relationship between a thickness T₁ of a levelling layer and a levelling rate;

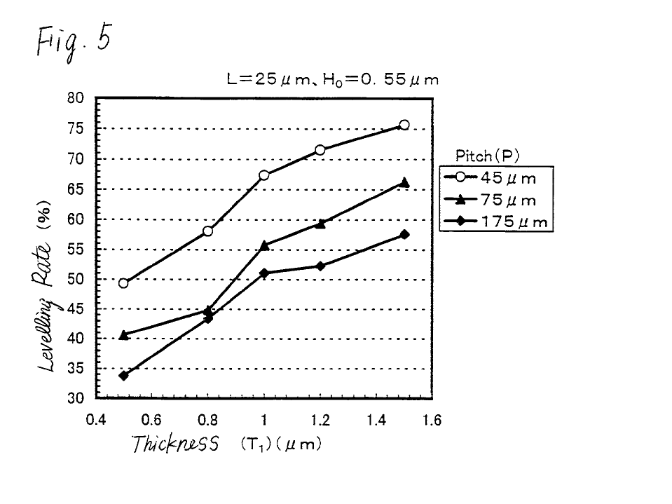

FIG. 6 is a graph showing the relationship between T₂/T₁ and a levelling rate;

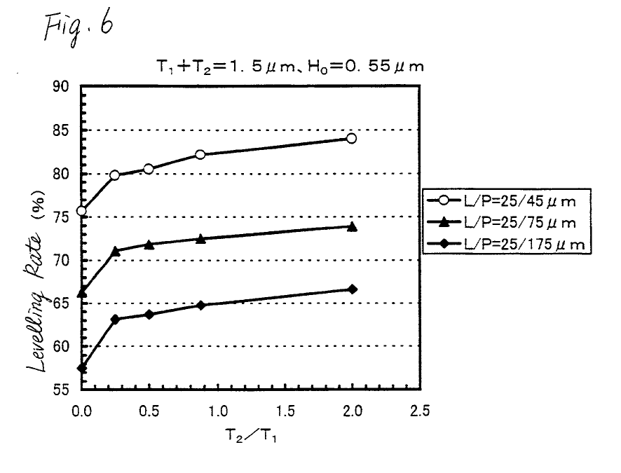

FIGS. 7A to 7G are diagrams showing a fabrication process of a pixel portion according to Embodiment 1 of the present invention;

FIGS. 8A to 8E are diagrams showing the fabrication process of the pixel portion according to Embodiment 1 of the present invention;

FIGS. 9A to 9C are diagrams showing the fabrication process of the pixel portion according to Embodiment 1 of the present invention;

FIG. 10 is a cross-sectional view showing an active matrix liquid crystal display device;

FIG. 11 is a perspective view showing the active matrix liquid crystal display device;

FIG. 12 is a top view showing the structure of an active matrix EL display device;

FIG. 13 is a cross-sectional view showing the structure of the active matrix EL display device; and

FIGS. 14A to 14F are diagrams showing examples of electric appliance.

### DETAILED DESCRIPTION OF THE PREFERRED EMBODIMENTS

A fabrication process of a liquid crystal display device having a structure of a levelling film according to the present invention will be described with reference to the drawings.

### Embodiment 1

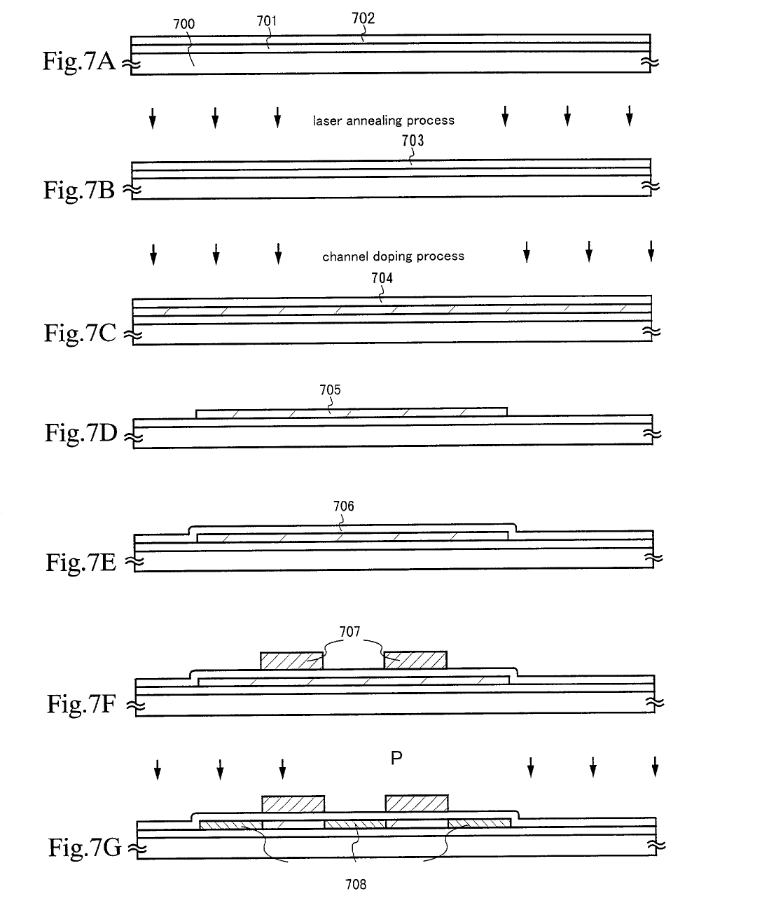

Embodiment 1 of the present invention will be described with reference to FIGS. 7A to 9C. A method of fabricating an active matrix substrate, particularly a pixel portion, will be herein described. The pixel portion includes a pixel TFT region that is a TFT provided in a pixel and a display region that does not include the TFT region.

In FIG. 7A, a glass substrate or a quartz substrate can be used as a substrate 700. A silicon substrate, a metal substrate or a stainless substrate on which an insulating film is formed may also be used for the substrate 700. A plastic substrate having a sufficient heat resistance can also be used.

Then, on the surface of the substrate 700 where a TFT is to be formed, a base film 701 made of an insulating film containing silicon is formed. In this embodiment, a silicon nitride oxide film having a thickness of 200 nm is formed as the base film 701.

Successively, an amorphous semiconductor film (in this embodiment, an amorphous silicon film) 702 having a thickness in the range of 20 to 100 nm is formed on the base film 701 by a known film-formation method. In addition to an amorphous silicon film, an amorphous compound semiconductor film such as an amorphous silicon germanium film may also be used as the amorphous semiconductor film.

Then, in accordance with the technique described in Japanese Patent Application Laid-open No. Hei 7-130652 (corresponding to U.S. Pat. No. 5,643,826), a semiconductor film containing crystal structures (a crystalline silicon film in this embodiment) 703 is formed. The technique described in the above publication concerns crystallizing means that utilizes a catalyst element (one or a plurality of elements, selected from the group consisting of nickel, cobalt, germanium, tin, lead, palladium, iron, and copper; typically, nickel) for promoting crystallization when the amorphous silicon film is to be crystallized.

Specifically, a thermal treatment is conducted with the catalyst element being held on the surface of the amorphous silicon film so as to transform the amorphous silicon film into a crystalline silicon film. Although the technique described in Embodiment 1 of the above publication is used in this embodiment, the technique described in Embodiment 2 thereof may alternatively be used. Although the crystalline silicon film includes a single-crystalline silicon film and a polycrystalline silicon film, the crystalline silicon film formed in this embodiment is a silicon film including crystal grain boundaries.

It is desirable that the amorphous silicon film is subjected to a dehydrogenation treatment through heating preferably at 400 to 550° C. for a few hours to reduce the amount of contained hydrogen to 5 atom % or less before performing the successive steps of crystallization, although these values depend on the amount of hydrogen contained in the amorphous silicon film. The amorphous silicon film may be formed by another fabrication method such as sputtering or evaporation. In such a case, it is desirable to reduce an impurity element such as oxygen, nitrogen or the like contained in the film to an allowable level.

Next, a known technique is used for the amorphous silicon film 702 to form a crystalline silicon film (a polysilicon film or a polycrystalline silicon film) 703 (FIG. 7B). In this embodiment, the amorphous silicon film 702 is irradiated with light emitted from a laser (a laser beam) to form the crystalline silicon film 703. A pulsed-oscillation or a continuous-wave excimer laser can be used as the laser. In addition to these excimer lasers, a continuous-wave argon laser may be used. Alternatively, a second harmonic, a third harmonic or a fourth harmonic emitted from an Nd:YAG laser or an Nd:YVO₄ laser may be used. The beam shape of laser light may be linear (including an oblong shape) or rectangular.

Instead of laser light, light emitted from a lamp (lamp light) may be used for the irradiation (hereinafter, referred to as lamp annealing). As lamp light, light emitted from a halogen lamp, an infrared lamp or the like may be used.

The process for conducting a thermal treatment (annealing) using laser light or lamp light in this manner is referred to as a light annealing process. The light annealing process allows an effective thermal treatment process to be conducted with a high throughput even when a substrate with a low heat resistance such as a glass substrate is used because the light annealing process permits a high-temperature thermal treatment in a short period of time. It is obvious that furnace annealing using an electrical furnace (also referred to as thermal annealing) may alternatively be used for the annealing process.

In this embodiment, pulse-oscillation excimer laser light is processed into a linear shape to conduct the laser annealing process. The laser annealing conditions are set as follows: an XeCl gas used as an excitation gas; a room temperature set as a treatment temperature; 30 Hz of a pulse-emission frequency; a laser energy density in the range of 250 to 500 mJ/cm² (typically in the range of 350 to 400 mJ/cm²).

The laser annealing process conducted under the above conditions has the effects of completely crystallizing an amorphous region remaining uncrystallized after the thermal crystallization and of reducing the defects of the previously crystallized crystalline region or the like. Therefore, this process may be referred to as a process for improving the crystallinity of the semiconductor film by light annealing or a process for promoting the crystallization of the semiconductor film. Such effects can also be obtained by optimizing the conditions of lamp annealing.

Next, a protective film 704 is formed on the crystalline silicon film 703 for successive addition of an impurity. As the protective film 704, a silicon nitride oxide film or a silicon oxide film having a thickness of 100 to 200 nm (preferably 130 to 170 nm) is used. The protective film 704 serves not to directly expose the crystalline silicon film 703 to plasma upon addition of the impurity and to permit fine control of the concentration.

Successively, an impurity element for imparting a p-type conductivity (hereinafter, referred to as a p-type impurity element) is added through the protective film 704. As the p-type impurity element, elements that are members of Group 13 in the periodic table, typically boron or gallium, may be used. This process (referred to as a channel doping process) is for controlling a threshold voltage of the TFT. In this example, boron is added by an ion doping method in which diborane (B₂H₆) is excited by plasma without mass separation. It is apparent that an ion implantation method with mass separation may also be used.

Through this process, an impurity region 705 containing the p-type impurity element (boron in this embodiment) at a concentration in the range of 1×10¹⁵ to 1×10¹⁸ atoms/cm³ (typically, 5×10¹⁶ to 5×10¹⁷ atoms/cm³) is formed. In this specification, an impurity region containing the p-type impurity element at least at the concentration within the above range is defined as a p-type impurity region (b) (FIG. 7C).

Next, after removal of the protective film 704, an unnecessary portion of the crystalline silicon film is removed to form an island-like semiconductor film (hereinafter, referred to as an active layer) 705 (FIG. 7D).

Next, a gate insulating film 706 is formed so as to cover the active layer 705. The gate insulating film 706 may be formed to have a thickness in the range of 10 to 200 nm, preferably, in the range of 50 to 150 nm. In this embodiment, a silicon nitride oxide film made from N₂O and SiH₄ by a plasma CVD method is formed to have a thickness of 115 nm (FIG. 7E).

Next, a laminate film of not-shown two layers, i.e., a tungsten nitride (WN) layer having a thickness of 50 nm and a tantalum (Ta) layer having a thickness of 350 nm, is formed as a gate wiring 707 (FIG. 7F). Although the gate wiring may be formed of a single-layer electrically conductive film, it is preferred to form the gate wiring by using a laminate film of two layers or three layers, or more, if necessary.

In this embodiment, a double gate is adopted as shown in FIG. 7F. It is effective to utilize a multi-gate system as a countermeasure of leakage of the gate. As the gate wiring, an element selected from the group consisting of tantalum (Ta), titanium (Ti), molybdenum (Mo), tungsten (W), chromium (Cr) and silicon (Si), or an alloy film formed of the combination thereof (typically, an Mo-W alloy or an Mo-Ta alloy) can be used.

Next, an n-type impurity element (in this embodiment, phosphorus) is added in a self-aligning manner using the gate wiring 707 as a mask. The addition of phosphorus is controlled so that the thus formed impurity region 708 has the concentration of phosphorus which is 5 to 10 times higher (typically, 1×10¹⁶ to 5×10¹⁸ atoms/cm³, more typically, 3×10¹⁷ to 3×10¹⁸ atoms/cm³) than that of boron added in the above-described channel doping process. In this specification, the impurity region containing the n-type impurity element within the above concentration range is defined as an n-type impurity region (c) (FIG. 7G).

Although boron is already added to the above p-type impurity region (b) 705 at the concentration in the range of 1×10¹⁵ to 1×10¹⁸ atoms/cm³ in the channel doping process, it may be considered that boron does not affect the function of the p-type impurity region (b) because phosphorus is added in this process at the concentration which is 5 to 10 times higher than that of boron contained in the p-type impurity region (b) 705.

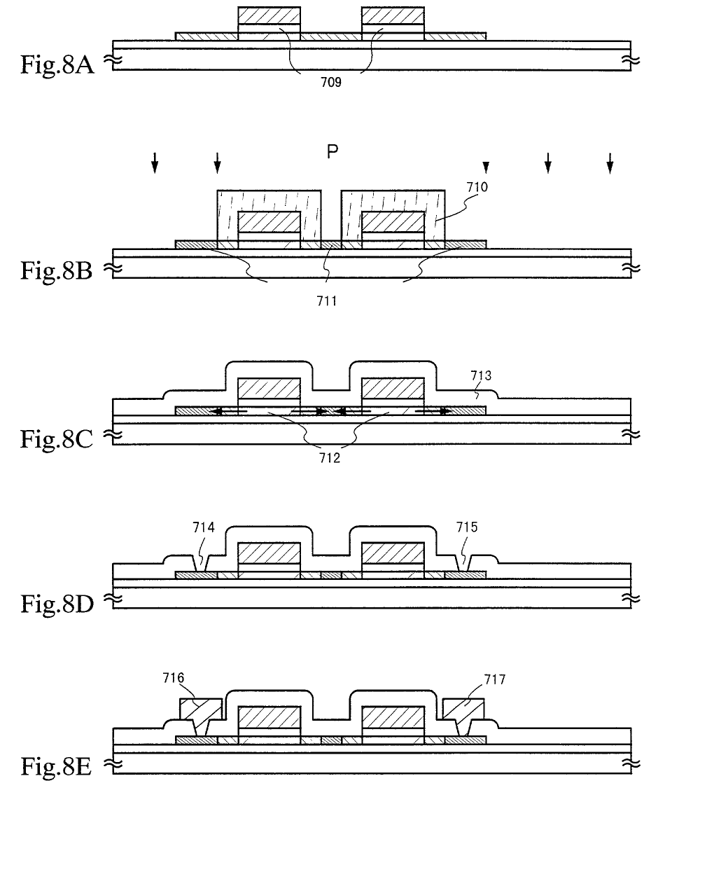

Next, the gate insulating film 706 is etched in a self-aligning manner using the gate wiring 707 as a mask. A dry etching method is used for the etching. Although a CHF₃ gas is herein used as an etching gas, the etching gas is not necessarily limited thereto. In this way, a gate insulating film 709 is formed under the gate wiring 707 (FIG. 8A).

By exposing the active layer in this manner, an acceleration voltage can be lowered when a successive step for adding an impurity element is performed. Moreover, a throughput is improved owing to a small dose. It is apparent that the impurity region also can be formed by through doping with the gate insulating film being left unetched.

Next, a resist mask 710 is formed so as to cover the gate wiring 709. Then, an n-type impurity element (in this embodiment, phosphorus) is added to form an impurity region 711 containing phosphorus at a high concentration. The n-type impurity element is added again by an ion doping method using phosphin (PH₃) (it is obvious that an ion implantation method may be used instead). The impurity region 711 has a concentration of phosphorus in the range of 1×10²⁰ to 1×10²¹ atoms/cm³ (typically, in the range of 2×10²⁰ to 5×10²⁰ atoms/cm³) (FIG. 8B).

In this specification, an impurity region containing an n-type impurity element in the above range of concentration is defined as an n-type impurity region (a). Although the region where the impurity region 711 is formed contains phosphorus or boron already added in the previous process, the effects of phosphorus or boron may be neglected because phosphorus is added at a sufficiently high concentration in this process. Therefore, the impurity region 711 may also be referred to as the n-type impurity region (a) in this specification.

Next, after removal of the resist mask 710, a first interlayer insulating film 713 is formed. The first interlayer insulating film 713 may be made of an insulating film containing silicon, more specifically, a silicon nitride film, a silicon oxide film, a silicon nitride oxide film or a laminate film of the combination thereof. The thickness of the film may be set within the range of 600 nm to 1.5 μm. In this embodiment, a silicon nitride oxide film (having a nitride concentration in the range of 25 to 50 atomic %) having a thickness of 1 μm formed by a plasma CVD method using SiH₄, N₂O and NH₃ as material gases is used.

Thereafter, a thermal treatment is performed to activate the n-type or p-type impurity element added at the respective concentrations. This process is performed by using a furnace annealing method, a laser annealing method, or a rapid thermal annealing method (RTA method). In this embodiment, the activation process is carried out by a furnace annealing method. The thermal treatment is conducted in a nitrogen atmosphere at a temperature in the range of 300 to 650° C., preferably in the range of 400 to 550° C., 550° C. in this embodiment, for four hours (FIG. 8C).

At this point, the catalyst element (in this embodiment, nickel) used for crystallization of the amorphous silicon film in this embodiment moves toward the direction indicated with the arrows in the drawing to be gettered in the region 711 containing phosphorus at a high concentration and formed in the above process shown in FIG. 8B. This phenomenon results from the effects of phosphorus gettering a metal element. As a result of this phenomenon, a region 712 where a channel is to be formed in the successive step has the catalyst element at a concentration of 1×10¹⁷ atoms/cm³ or less (preferably, 1×10¹⁶ atoms/cm³ or less).

On the other hand, a region serving as a gettering site of the catalyst element (the impurity region 711 formed by the process shown in FIG. 8B) contains the catalyst element at a high concentration of 5×10¹⁸ atoms/cm³ or more (typically, 1×10¹⁹ to 5×10²⁰ atoms/cm³) due to segregation of the catalyst element.

Furthermore, in the atmosphere containing hydrogen in the range of 3 to 100%, a thermal treatment at 300 to 450° C. is conducted for 1 to 12 hours to perform a process for hydrogenating the active layer. This process is for terminating a dangling bond in the semiconductor layer with thermally excited hydrogen. In order to hydrogenate the active layer, plasma hydrogenation (using hydrogen excited by plasma) may be conducted instead.

Then, after the formation of through holes 714 and 715 reaching the source region and the drain region of the TFT (FIG. 8D), a source wiring 716 and a drain wiring 717 are formed (FIG. 8E). Although not shown, a Ti film with a thickness of 100 nm, an aluminum film containing Ti with a thickness of 300 nm, and a Ti film with a thickness of 150 nm are successively formed by sputtering so as to form these wiring as three-layered laminate films in this embodiment.

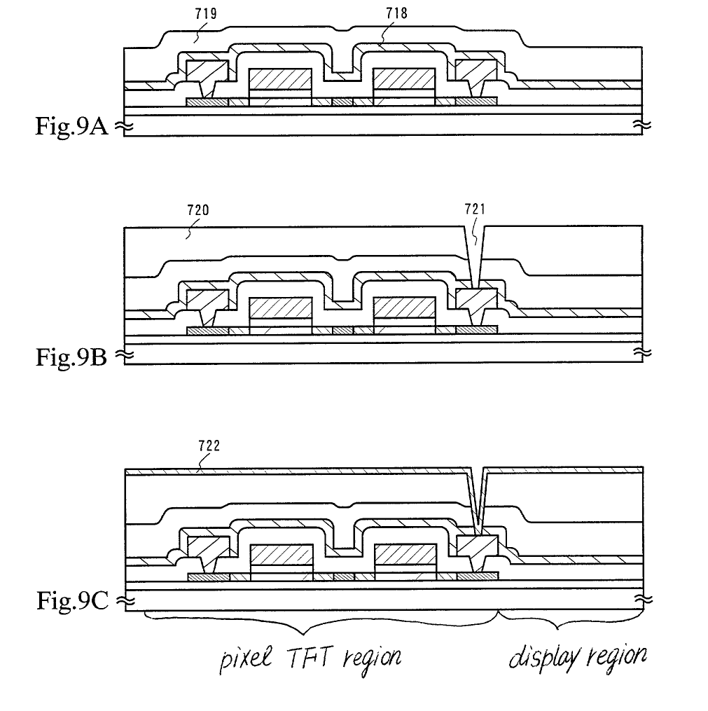

Next, a silicon nitride film, a silicon oxide film, or a silicon nitride oxide film is formed to have a thickness of 50 to 500 nm (typically, 200 to 300 nm) as a passivation film 718. In this embodiment, prior to the formation of the film, a plasma treatment is conducted using a gas containing hydrogen such as H₂ or NH₃. Then, after the formation of the film, a thermal treatment is conducted. By this pre-treatment, excited hydrogen is supplied to the first interlayer insulating film 713. To conduct the thermal treatment under such a condition improves the quality of the passivation film 718 while the active layer can be effectively hydrogenated owing to the downward diffusion of hydrogen added to the first interlayer insulating film 713 (FIG. 9A).

Another hydrogenation process may be conducted after the formation of the passivation film 718. For example, a thermal treatment is conducted at 300 to 450° C. for 1 to 12 hours in the atmosphere containing hydrogen at 3 to 100%. Alternatively, similar effects can be obtained by using plasma hydrogenation. An aperture may be formed in the passivation film 718 at the position where a through hole 721 for connecting the pixel electrode with the drain wiring 717 is to be subsequently formed.

Then, a first levelling film 719 is applied as a second interlayer insulating film onto the passivation film 718 by spin coating, and is then baked in an oven at 250° C. for 1 hour to obtain a thickness of 0.5 μm. As the first levelling film 719, a polyimide resin, an acrylic resin, a resin containing a siloxane structure, or an inorganic SOG material can be used. In this embodiment, an acrylic resin is used. The acrylic resin is frequently used for liquid crystal display devices for its low dielectric constant, excellent flatness, high transparency and low cost.

Furthermore, the acrylic resin is applied as a second levelling film 720 onto the first levelling film 719 by spin coating, and is then baked in an oven at 250° C. for 1 hour to form a film having a thickness of 1.0 μm. Since the first levelling film 719 has a thickness of 0.5 μm and the second levelling film 720 has a thickness of 1.0 μm, the total thickness of the films as the second interlayer insulating film is 1.5 μm. By forming the double-layered levelling film with the above thicknesses, higher flatness is realized as compared with a levelling film of a single layered structure.

Next, a through hole 721 reaching the drain wiring 717 is formed through the second levelling film 720, the first levelling film 719 and the passivation film 718. The through hole 721 may be formed by dry etching using a resist pattern. Alternatively, the through hole 721 can be formed by using a photosensitive levelling film.

Then, a pixel electrode 722 is formed. A transparent conductive film is used for the pixel electrode 722 in the case where a transmissive liquid crystal display device is to be fabricated, whereas a metal film may be used in the case where a reflective liquid crystal display device is to be fabricated. Since a transmissive liquid crystal display device is to be obtained in this embodiment, an electrically conductive oxide film made of a compound of indium oxide and tin oxide (ITO film) is formed to a thickness of 110 nm by sputtering.

In this manner, a pixel TFT region consisting of the n-channel TFT and a display region are formed in the pixel portion, thereby obtaining a flat surface of the pixel electrode with the reduced level difference generated by the wiring.

### Embodiment 2

In Embodiment 2, the case where a pixel TFT having a different structure from that of Embodiment 1 is to be fabricated will be described. Since only a part of fabrication steps are different from those of Embodiment 1, the same fabrication steps are designated by the same reference numerals.

In accordance with the process of Embodiment 1, the fabrication steps up to the formation of the passivation film 718 are conducted. The first levelling film 719 is formed to a thickness of 0.3 μm (FIG. 9A). Then, the second levelling film 720 is formed to a thickness of 1.2 μm on the first levelling film 719. As the first levelling film 719 and the second levelling film 720, a polyimide resin, an acrylic resin, a resin containing a siloxane structure or an inorganic SOG material can be used. In this embodiment, an acrylic resin is used.

Since the first levelling film 719 has a thickness of 0.3 μm and the second levelling film 720 has a thickness of 1.2 μm, the total thickness of the films as the second interlayer insulating film is 1.5 μm. It is supposed that much higher flatness is realized as compared with the flatness obtained with the thicknesses in Embodiment 1 by forming the double-layered levelling film with the above thicknesses.

As the successive steps, the steps of Embodiment 1 shown in the drawings of FIG. 9B and from there on may be conducted. In this way, the pixel TFT region including the n-channel TFT and the display region are formed in the pixel portion, thereby obtaining a flat surface of the pixel electrode with the level differences generated by the wirings being further reduced.

### Embodiment 3

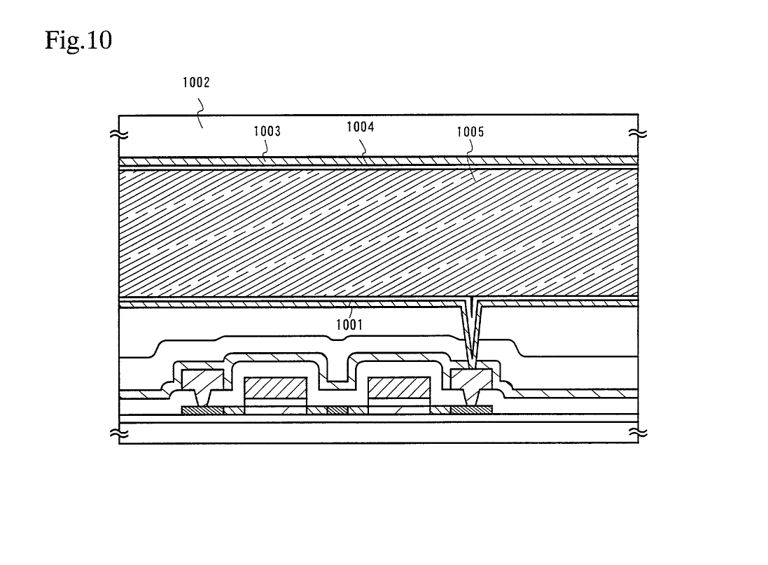

In this embodiment, the steps for fabricating an active matrix liquid crystal display device using the active matrix substrate fabricated in Embodiment 1 or Embodiment 2 will be described. As shown in FIG. 10, an orientation film 1001 is formed on the substrate in the state shown in FIG. 9C. A polyimide film is used as the orientation film in this embodiment. For a counter substrate 1002, a counter electrode 1003 and an orientation film 1004 are formed. A color filter or a shielding film may be formed on the counter substrate as needed.

Next, after formation of the orientation films, a rubbing treatment is performed so as to orient liquid crystal molecules at a certain pretilt angle. Then, the active matrix substrate on which the pixel portion and driving circuits are formed is bonded with the counter substrate by a known cell assembling step through a sealing material or a spacer (not shown). Thereafter, liquid crystal 1005 is injected into a gap between the substrates and is then completely sealed with an end-sealing material (not shown). A known liquid crystal material may be used as the liquid crystal 1005. In this manner, an active matrix liquid crystal display device shown in FIG. 10 is completed.

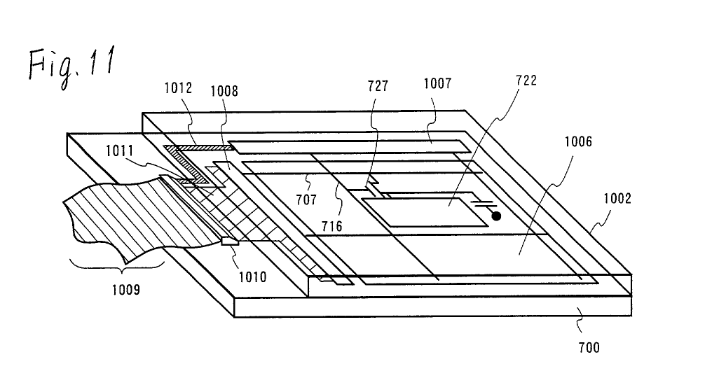

Next, the structure of this active matrix liquid crystal display device is described with reference to the perspective view of FIG. 11. In order to associate FIG. 11 with the cross-sectional views of the structure shown in FIGS. 7A through 9C, the same reference numerals are used in FIG. 11. The active matrix substrate is constituted of a pixel portion 1006, a gate signal driving circuit 1007, and an image (source) signal driving circuit 1008 which are formed on the glass substrate 700. The pixel TFT region 727 is an n-channel TFT. The driving circuits provided in the periphery of the pixel TFT region 727 are constituted based on CMOS circuits. The gate signal driving circuit 1007 and the image signal driving circuit 1008 are connected to the pixel portion 1006 by the gate wiring 716 and the source wiring 707, respectively. Connection wirings 1011 and 1012 from an external input/output terminal 1010, to which an FPC 1009 is connected, to input/output terminals of the driving circuits are provided.

### Embodiment 4

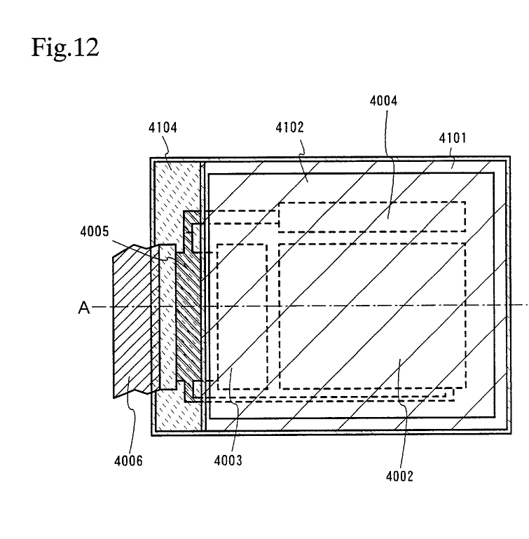

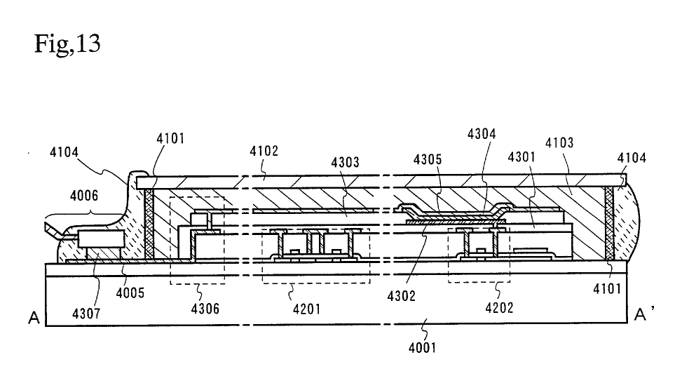

In this embodiment, the case where an Electro Luminescence (hereinafter, abbreviated as EL) display device, also called a light emitting device or a light emitting diode, is fabricated by using the present invention will be described. The EL is a light-emitting device having as a light source a layer containing an organic compound (EL element) that generates luminescence by applying an electric field thereto. The EL in the organic compound includes light emission (fluorescence) caused when the state transits from a singlet excited state to a ground state and light emission (phosphorescence) caused when the state transits from a triplet excited state to a ground state, and the EL device referred to in this specification include triplet-based light emission device or singlet-based light emission device, for example. FIG. 12 is a top view showing the EL display device according to the present invention, and FIG. 13 is a cross-sectional view thereof.

In FIGS. 12 and 13, a substrate is denoted by 4001, a pixel portion by 4002, a source side driving circuit by 4003, and a gate side driving circuit by 4004. Each of the driving circuits 4003 and 4004 is connected through a wiring 4005 to an FPC (Flexible Printed Circuit) 4006 and to external equipment.

A first sealing material 4101, a covering material 4102, a filler 4103 and a second sealing material 4104 are provided so as to enclose the pixel portion 4002, the source side driving circuit 4003, and the gate side driving circuit 4004.

FIG. 13 corresponds to a cross-sectional view taken along the line A-A′ of FIG. 12. On the substrate 4001, a driving TFT (herein, an n-channel TFT and a p-channel TFT are shown) 4201 contained in the source side driving circuit 4003 and a pixel TFT (herein, a TFT for controlling an electric current to the EL element is shown) 4202 included in the pixel portion 4002 are formed.

In this embodiment, the pixel TFT 4202 is fabricated by using the levelling structure according to the present invention. Specifically, the TFT having the same structure as that of the pixel portion shown in FIG. 9C is used for the pixel TFT 4202.

On the driving TFT 4201 and the pixel TFT 4202, an interlayer insulating film (levelling film) 4301 made of a resin material in accordance with the present invention is formed. Then, a pixel electrode (anode) 4302 electrically connected with the drain of the pixel TFT 4202 is formed thereon. A transparent electrically conductive film having a large work function is used as the pixel electrode 4302. As the transparent conductive film, a compound of indium oxide and tin oxide or a compound of indium oxide and zinc oxide can be used.

Then, an insulating film 4303 is formed on the pixel electrode 4302. An aperture is formed through the insulating film 4303 above the pixel electrode 4302. In this aperture, an EL layer 4304 is formed on the pixel electrode 4302. For the EL layer 4304, a known organic EL material or a known inorganic EL material can be used. For the organic EL material, any of a monomer type material and a polymer type material may be used.

As a method of forming the EL layer 4304, a known method may be used. The EL layer may have a single-layered structure or a multi-layered structure in which a hole injection layer, a hole transport layer, a light-emitting layer, an electron transport layer, and an electron injection layer are freely combined.

On the EL layer 4304, a cathode 4305 made of an electrically conducive film having a light-shielding property (typically, an electrically conductive film containing aluminum, copper or silver as a principal component, or a laminate film of such an electrically conductive film and another electrically conductive film) is formed. It is desirable to remove moisture or oxygen which is present at the interface between the cathode 4305 and the EL layer 4304 as much as possible. Therefore, it is necessary to successively form the cathode 4305 and the EL layer 4304 in vacuum or to form the EL layer 4304 in a nitrogen atmosphere or a rare gas atmosphere and form the cathode 4305 without contacting with oxygen or moisture. In this embodiment, the film formation as described above is made possible by using a film formation apparatus with the multi-chamber system (cluster tool system).

The cathode 4305 is electrically connected to the wiring 4005 in a region designated by the reference numeral 4306. The wiring 4005 is a wiring for applying a predetermined voltage to the cathode 4305, and is electrically connected to the FPC 4006 through an electrically conductive material 4307.

In the manner as described above, an EL element including the pixel electrode (anode) 4302, the EL layer 4304 and the cathode 4305 is formed. The EL element is enclosed by the first sealing material 4101 and the covering material 4102 bonded to the substrate 4001 by the first sealing material 4101, and is sealed by the filler 4103.

As the covering material 4102, a glass plate, a metal plate (typically, a stainless steel plate), a ceramic plate, an FRP (Fiberglass-Reinforced Plastics) plate, a PVF (polyvinyl fluoride) film, a Mylar film, a polyester film, or an acrylic film can be used. Alternatively, a seat having a structure in which an aluminum foil is interposed between PVF films or Mylar films may also be used.

In the case where light is radiated from the EL element toward the covering material, however, the covering material must be transparent. In such a case, a transparent material such as a glass plate, a plastic plate, a polyester film or an acrylic film is used.

As the filler 4103, an ultraviolet-curable resin or a thermosetting resin may be used: specifically, PVC (polyvinyl chloride), acrylic, polyimide, an epoxy resin, a silicone resin, PVB (polyvinyl butyral) or EVA (ethylene vinyl acetate) can be used. The EL element can be restrained from being deteriorated by providing a hygroscopic material (preferably, barium oxide) within the filler 4103.

Spacers may be contained in the filler 4103. In such a case, the spacers themselves can have a hygroscopic property by making the spacers of barium oxide. Moreover, in the case where the spacers are provided, it is effective to provide a resin film on the anode 4305 as a buffer layer for buffering the pressure applied by the spacers.

The wiring 4005 is electrically connected to the FPC 4006 via the electrically conductive material 4307. The wiring 4005 transmits, to the FPC 4006, signals to be sent to the pixel portion 4002, the source side driving circuit 4003 and the gate side driving circuit 4004, and the wiring 4005 is electrically connected to external equipment by the FPC 4006.

In this embodiment, the second sealing material 4104 is provided so as to cover an exposed region of the first sealing material 4101 and a part of the FPC 4006 to thoroughly isolate the EL element from the open air. In this manner, the EL display device having the cross-sectional structure shown in FIG. 13 is obtained. Alternatively, the EL display device of this embodiment may be fabricated to have the structure combined with the structure of Embodiment 1 or Embodiment 2.

### Embodiment 5

It is possible to carry out the present invention for the process (step) of levelling a level difference. The present invention can be applied not only to the case of fabricating the liquid crystal display device such as that of Embodiment 3 or the EL display device of Embodiment 4, but also to a technique of fabricating display devices including the process. The display devices herein include an image sensor, or an IC (integrated circuit).

As specific examples of the display device, a liquid crystal display device, an EL display device, an EC (electrochromic) display device, an FED (field emission display) are given.

As specific example of the image sensor, a CCD (charge coupled device) image sensor, a MOS image sensor, a CPD (charge priming device) image sensor and the like may be given. Furthermore, the present invention can be carried out for fabricating an IC such as a SRAM (static RAM), a DRAM (dynamic RAM) and a non-volatile MOS memory.

### Embodiment 6

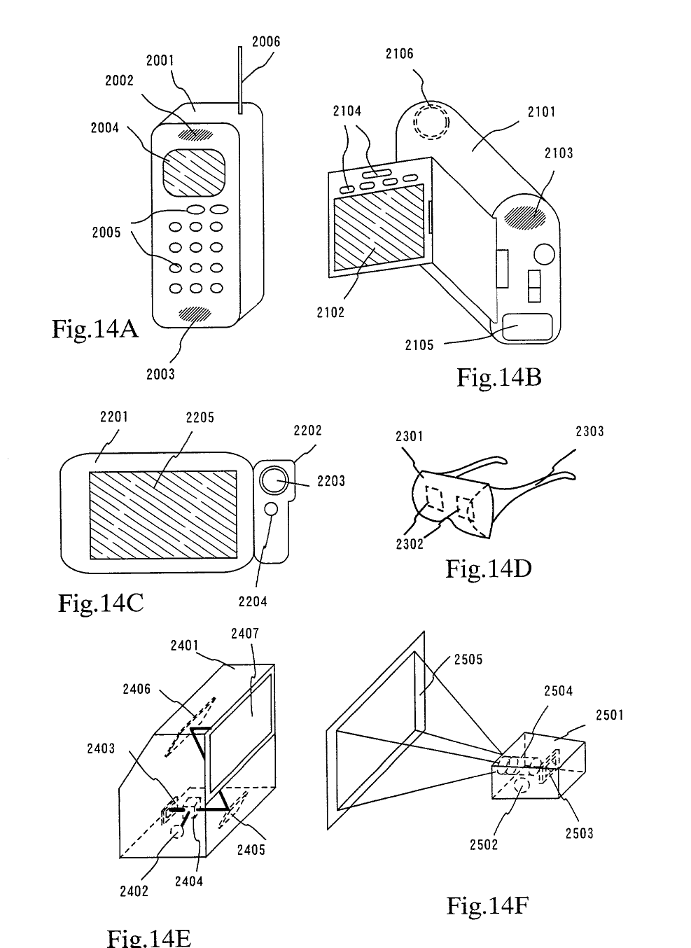

It is possible to use a display device fabricated employing the present invention as a display unit of an electronic appliance. As such an electronic equipment, video cameras, digital cameras, projectors, projection televisions, goggle type displays (head mount displays), navigation systems, acoustic reproduction devices, notebook personal computers, game machines, portable information terminals (such as mobile computers, portable telephones, portable-type game machines and electronic books), image reproduction devices having a recording medium, etc. are given. Some examples of these are shown in FIGS. 14A to 14F.

FIG. 14A shows a portable telephone, which is composed of a main body 2001, a sound output unit 2002, a sound input unit 2003, a display unit 2004, operation switches 2005, and an antenna 2006. The present invention can be applied to the display unit 2004.

FIG. 14B shows a video camera, which is composed of a main body 2101, a display unit 2102, a sound input unit 2103, operation switches 2104, a battery 2105, and an image receiving unit 2106. The present invention can be applied to the display unit 2102.

FIG. 14C shows a mobile computer, which is composed of a main body 2201, a camera unit 2202, an image receiving unit 2203, operating switches 2204, and a display unit 2205. The present invention can be applied to the display unit 2205.

FIG. 14D shows a goggle type display, which is composed of a main body 2301, display units 2302, and arm units 2303. The present invention can be applied to the display units 2302.

FIG. 14E shows a rear type projector (projection television), and is composed of a main body 2401, a light source 2402, a display device 2403, a polarizing beam splitter 2404, reflectors 2405 and 2406 and a screen 2407. The present invention may be applied to the display device 2403.

FIG. 14F shows a front projector, which is composed of a main body 2501, a light source 2502, a display device 2503, an optical system 2504 and a screen 2505. The present invention can be applied to the display device 2503.

As described above, an applicable range of the present invention is extremely wide, and it can be applied to electric appliances in all fields. Further, the fabrication of the electric appliances of Embodiment 6 can be realized by using a structure obtained by combining any of Embodiments 1 to b 5.

With the active matrix substrate fabricated by using the present invention, the level differences generated by wirings can be further levelled without increasing the thickness of a conventional interlayer insulating film. Therefore, the wirings formed on the levelling film are prevented from being broken to improve the reliability of the wirings. Moreover, since the occurrence of poor orientation of liquid crystal can be reduced, the display quality can be improved without making a sacrifice of the aperture ratio even if a light-shielding pattern is provided.

Furthermore, by fabricating a display device using the present invention, the quality and reliability of electric appliances using the display device as a display unit can also be improved.

What is claimed is:

1. A method of fabricating a display device, wherein the thickness of a first levelling film formed above a wiring is thinner than that of a second levelling film formed on the first levelling film.

2. A method of fabricating a display device, wherein the thickness of a first levelling film formed above a wiring is thinner than that of a second levelling film formed on the first levelling film, and wherein the thickness of the first levelling film is 0.1 μm or more and less than 1.5 μm.

3. A method of fabricating a display device, wherein the thickness of a first levelling film formed above a wiring is thinner than that of a second levelling film formed on the first levelling film, and wherein the thickness of the second levelling film is from 0.1 μm to 2.9 μm inclusive.

4. A method of fabricating a display device, wherein the thickness of a first levelling film formed above a wiring is thinner than that of a second levelling film formed on the first levelling film, and wherein the total thickness of the first levelling film and the second levelling film is from 0.2 μm to 3.0 μm inclusive.

5. A method of fabricating a display device, wherein the thickness of a first levelling film formed above a wiring is thinner than that of a second levelling film formed on the first levelling film, and wherein the first levelling film and the second levelling film are insulating films formed by spin coating.

6. A method of fabricating a display device, wherein the thickness of a first levelling film formed above a wiring is thinner than that of a second levelling film formed on the first levelling film, and wherein the first levelling film and the second levelling film are made of any of a polyimide resin, an acrylic resin, a resin containing a siloxane structure, and an inorganic SOG material.

7. A method of fabricating a display device, wherein the thickness of a first levelling film formed above a wiring is thinner than that of a second levelling film formed on the first levelling film, and wherein the first levelling film and the second levelling film are made of the same material.
